(19) United States
(12) Patent Application Publication
(10) Pub. No.: US 2015/0041933 A1
(43) Pub. Date: Feb. 12, 2015

(54) METHOD AND SYSTEM FOR PROVIDING MAGNETIC JUNCTIONS USING BCC COBALT AND SUITABLE FOR USE IN SPIN TRANSFER TORQUE MEMORIES

(71) Applicant: Samsung Electronics Co., LTD., Gyeonggi-do (KR)

(72) Inventors: Roman Chepulskyy, Milpitas, CA (US); Dmytro Apalkov, San Jose, CA (US); Xueti Tang, San Jose, CA (US); Keith Chan, San Jose, CA (US); Mohamad Towfik Krounbi, San Jose, CA (US)

(73) Assignee: Samsung Electronics Co., LTD., Gyeonggi-do (KR)

(21) Appl. No.: 14/048,164

(22) Filed: Oct. 8, 2013

Related U.S. Application Data
(60) Provisional application No. 61/863,822, filed on Aug. 8, 2013.

(51) Int. Cl. H01L 43/02

(52) U.S. Cl. CPC H01L 43/02
USPC 257/421

(57) ABSTRACT

A method and system for providing a magnetic junction usable in a magnetic device are described. The magnetic junction includes a pinned layer, a nonmagnetic spacer layer, and a free layer. The nonmagnetic spacer layer is between the pinned layer and the free layer. The free layer includes body-centered cubic Co. The magnetic junction is configured such that the free layer is switchable between a plurality of stable magnetic states when a write current is passed through the magnetic junction.

### CROSS-REFERENCE TO RELATED APPLICATIONS

This application claims the benefit of provisional Patent Application Ser. No. 61/863,822, filed Aug. 8, 2013, entitled METHOD AND SYSTEM FOR PROVIDING MAGNETIC JUNCTIONS USING BCC COBALT, assigned to the assignee of the present application, and incorporated herein by reference.

### BACKGROUND OF THE INVENTION

Magnetic memories, particularly magnetic random access memories (MRAMs), have drawn increasing interest due to their potential for high read/write speed, excellent endurance, non-volatility and low power consumption during operation. An MRAM can store information utilizing magnetic materials as an information recording medium. One type of MRAM is a spin transfer torque random access memory (STT-MRAM). STT-MRAM utilizes magnetic junctions written at least in part by a current driven through the magnetic junction. A spin polarized current driven through the magnetic junction exerts a spin torque on the magnetic moments in the magnetic junction. As a result, layer(s) having magnetic moments that are responsive to the spin torque may be switched to a desired state.

For example, FIG. 1 depicts a conventional magnetic tunneling junction (MTJ) 10 as it may be used in a conventional STT-MRAM. The conventional MTJ 10 typically resides on a bottom contact 11, uses conventional seed layer(s) 12 and includes a conventional antiferromagnetic (AFM) layer 14, a conventional pinned layer 16, a conventional tunneling barrier layer 18, a conventional free layer 20, and a conventional capping layer 22. Also shown is top contact 24.

Conventional contacts 11 and 24 are used in driving the current in a current-perpendicular-to-plane (CPP) direction, or along the z-axis as shown in FIG. 1. The conventional seed layer(s) 12 are typically utilized to aid in the growth of subsequent layers, such as the AFM layer 14, having a desired crystal structure. The conventional tunneling barrier layer 18 is nonmagnetic and is, for example, a thin insulator such as MgO.

The conventional pinned layer 16 and the conventional free layer 20 are magnetic. The magnetization 17 of the conventional pinned layer 16 is fixed, or pinned, in a particular direction, typically by an exchange-bias interaction with the AFM layer 14. Although depicted as a simple (single) layer, the conventional pinned layer 16 may include multiple layers. For example, the conventional pinned layer 16 may be a synthetic antiferromagnetic (SAF) layer including magnetic layers antiferromagnetically coupled through thin conductive layers, such as Ru. In such a SAF, multiple magnetic layers interleaved with a thin layer of Ru may be used. In another embodiment, the coupling across the Ru layers can be ferromagnetic. Further, other versions of the conventional MTJ 10 might include an additional pinned layer (not shown) separated from the free layer 20 by an additional nonmagnetic barrier or conductive layer (not shown).

The conventional free layer 20 has a changeable magnetization 21. Although depicted as a simple layer, the conventional free layer 20 may also include multiple layers. For example, the conventional free layer 20 may be a synthetic layer including magnetic layers antiferromagnetically or ferromagnetically coupled through thin conductive layers, such as Ru. Although shown as in-plane, the magnetization 21 of the conventional free layer 20 may have a perpendicular anisotropy. Thus, the pinned layer 16 and free layer 20 may have their magnetizations 17 and 21, respectively oriented perpendicular to the plane of the layers.

To switch the magnetization 21 of the conventional free layer 20, a current is driven perpendicular to plane (in the z-direction). When a sufficient current is driven from the top contact 24 to the bottom contact 11, the magnetization 21 of the conventional free layer 20 may switch to be parallel to the magnetization 17 of the conventional pinned layer 16. When a sufficient current is driven from the bottom contact 11 to the top contact 24, the magnetization 21 of the free layer may switch to be antiparallel to that of the pinned layer 16. The differences in magnetic configurations correspond to different magnetoresistances and thus different logical states (e.g. a logical “0” and a logical “1”) of the conventional MTJ 10.

Because of their potential for use in a variety of applications, research in magnetic memories is ongoing. For example, mechanisms for improving the performance of STT-RAM are desired. Accordingly, what is needed is a method and system that may improve the performance of the spin transfer torque based memories. The method and system described herein address such a need.

### BRIEF SUMMARY OF THE INVENTION

A method and system for providing a magnetic junction usable in a magnetic device are described. The magnetic junction includes a pinned layer, a nonmagnetic spacer layer, and a free layer. The nonmagnetic spacer layer is between the pinned layer and the free layer. The free layer includes body-centered cubic Co. The magnetic junction is configured such that the free layer is switchable between a plurality of stable magnetic states when a write current is passed through the magnetic junction.

### BRIEF DESCRIPTION OF SEVERAL VIEWS OF THE DRAWINGS

FIG. 1 depicts a conventional magnetic junction.

FIG. 2 depicts an exemplary embodiment of a magnetic junction usable in a magnetic memory programmable using spin transfer torque and which includes BCC Co in the free layer.

FIG. 3 depicts another exemplary embodiment of a magnetic junction usable in a magnetic memory programmable using spin transfer torque and which includes BCC Co in the free layer.

FIG. 4 depicts an exemplary embodiment of a magnetic structure including BCC Co and that is usable in a magnetic junction programmable using spin transfer torque.

FIG. 5 depicts another exemplary embodiment of a magnetic structure including BCC Co and that is usable in a magnetic junction programmable using spin transfer torque.

FIG. 6 depicts exemplary embodiment of a magnetic structure including BCC Co and that is usable in a magnetic junction programmable using spin transfer torque.

FIG. 7 depicts exemplary embodiment of a magnetic structure including BCC Co and that is usable in a magnetic junction programmable using spin transfer torque.

FIG. 8 depicts another exemplary embodiment of a magnetic structure including BCC Co and that is usable in a magnetic junction programmable using spin transfer torque.

FIG. 9 depicts another exemplary embodiment of a magnetic structure including BCC Co and that is usable in a magnetic junction programmable using spin transfer torque.

FIG. 10 depicts another exemplary embodiment of a magnetic structure including BCC Co and that is usable in a magnetic junction programmable using spin transfer torque.

FIG. 11 depicts another exemplary embodiment of a magnetic structure including BCC Co and that is usable in a magnetic junction programmable using spin transfer torque.

FIG. 12 depicts another exemplary embodiment of a magnetic structure including BCC Co and that is usable in a magnetic junction programmable using spin transfer torque.

FIG. 13 depicts another exemplary embodiment of a magnetic junction usable in a magnetic memory programmable using spin transfer torque and which includes BCC Co in the free layer.

FIG. 14 depicts another exemplary embodiment of a magnetic junction usable in a magnetic memory programmable using spin transfer torque and which includes BCC Co in the free layer.

FIG. 15 depicts an exemplary embodiment of a memory utilizing magnetic junctions in the memory element(s) of the storage cell(s)

FIG. 16 depicts an exemplary embodiment of a method for providing a magnetic junction usable in a magnetic memory programmable using spin transfer torque and which includes BCC Co in the free layer.

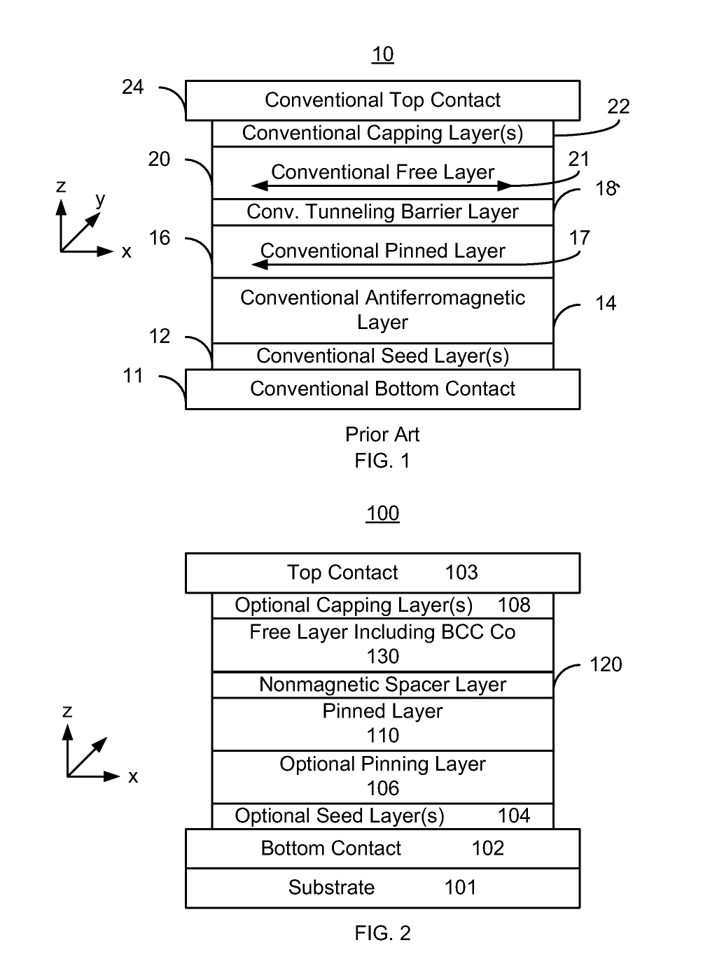

### DETAILED DESCRIPTION OF THE INVENTION

The exemplary embodiments relate to magnetic junctions usable in magnetic devices, such as magnetic memories, and the devices using such magnetic junctions. The following description is presented to enable one of ordinary skill in the art to make and use the invention and is provided in the context of a patent application and its requirements. Various modifications to the exemplary embodiments and the generic principles and features described herein will be readily apparent. The exemplary embodiments are mainly described in terms of particular methods and systems provided in particular implementations. However, the methods and systems will operate effectively in other implementations. Phrases such as “exemplary embodiment”, “one embodiment” and “another embodiment” may refer to the same or different embodiments as well as to multiple embodiments. The embodiments will be described with respect to systems and/or devices having certain components. However, the systems and/or devices may include more or less components than those shown, and variations in the arrangement and type of the components may be made without departing from the scope of the invention. The exemplary embodiments will also be described in the context of particular methods having certain steps. However, the method and system operate effectively for other methods having different and/or additional steps and steps in different orders that are not inconsistent with the exemplary embodiments. Thus, the present invention is not intended to be limited to the embodiments shown, but is to be accorded the widest scope consistent with the principles and features described herein.

The exemplary embodiments include magnetic junction(s) usable in magnetic device(s). For example, the magnetic junction(s) may be within magnetic storage cells for a magnetic memory programmable using spin transfer torque. The magnetic memories may be usable in electronic devices that make use of nonvolatile storage. Such electronic devices include but are not limited to cellular phones, tablets, and other mobile computing devices. The magnetic junction includes a pinned layer, a nonmagnetic spacer layer, and a free layer. The nonmagnetic spacer layer is between the pinned layer and the free layer. The free layer includes body-centered cubic Co. The magnetic junction is configured such that the free layer is switchable between a plurality of stable magnetic states when a write current is passed through the magnetic junction.

The exemplary embodiments are described in the context of particular magnetic junctions and magnetic memories having certain components. One of ordinary skill in the art will readily recognize that the present invention is consistent with the use of magnetic junctions and magnetic memories having other and/or additional components and/or other features not inconsistent with the present invention. The method and system are also described in the context of current understanding of the spin transfer phenomenon, of magnetic anisotropy, and other physical phenomenon. Consequently, one of ordinary skill in the art will readily recognize that theoretical explanations of the behavior of the method and system are made based upon this current understanding of spin transfer, magnetic anisotropy and other physical phenomena. However, the method and system described herein are not dependent upon a particular physical explanation. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the method and system are described in the context of magnetic junctions and/or substructures having particular layers. However, one of ordinary skill in the art will readily recognize that magnetic junctions and/or substructures having additional and/or different layers not inconsistent with the method and system could also be used. Moreover, certain components are described as being magnetic, ferromagnetic, and ferrimagnetic. As used herein, the term magnetic could include ferromagnetic, ferrimagnetic or like structures. Thus, as used herein, the term “magnetic” or “ferromagnetic” includes, but is not limited to ferromagnets and ferrimagnets. The method and system are also described in the context of single magnetic junctions and substructures. However, one of ordinary skill in the art will readily recognize that the method and system are consistent with the use of magnetic memories having multiple magnetic junctions and using multiple substructures. Further, as used herein, “in-plane” is substantially within or parallel to the plane of one or more of the layers of a magnetic junction. Conversely, “perpendicular” corresponds to a direction that is substantially perpendicular to one or more of the layers of the magnetic junction.

FIG. 2 depicts an exemplary embodiment of a magnetic junction 100 as well as surrounding structures. For clarity, FIG. 2 is not to scale. The magnetic junction may be used in a magnetic device such as a spin transfer torque random access memory (STT-RAM) and, therefore, in a variety of electronic devices. The magnetic junction 100 includes a pinned layer 110, a nonmagnetic spacer layer 120, and a free layer 130. Also shown is an underlying substrate 101 in which devices including but not limited to a transistor may be formed. Although layers 110, 120, and 130 are shown with a particular orientation with respect to the substrate 101, this orientation may vary in other embodiments. For example, the pinned layer 110 may be closer to the top (furthest from a substrate) of the magnetic junction 100. Also shown are optional seed layer 104, optional pinning layer 106, and optional capping layer 108. The optional pinning layer 106 may be used to fix the magnetization (not shown) of the pinned layer 110. In some embodiments, the optional pinning layer 106 may be an AFM layer or multilayer that pins the magnetization (not shown) of the pinned layer 110 by an exchange-bias interaction. However, in other embodiments, the optional pinning layer 106 may be omitted or another structure may be used. For example, if the perpendicular magnetic anisotropy energy of the pinned layer 110 exceeds the out of plane demagnetization energy, the magnetic moment of the pinned layer 110 may be perpendicular to plane. In such embodiments, the pinning layer 106 may be omitted. The magnetic junction 100 is also configured to allow the free layer 130 to be switched between stable magnetic states when a write current is passed through the magnetic junction 100. Thus, the free layer 130 is switchable utilizing spin transfer torque.

The pinned layer 110 is magnetic and may have its magnetization pinned, or fixed, in a particular direction during at least a portion of the operation of the magnetic junction. Although depicted as a simple layer, the pinned layer 110 may include multiple layers. For example, the pinned layer 110 may be a synthetic antiferromagnet (SAF) including magnetic layers antiferromagnetically or ferromagnetically coupled through thin layers, such as Ru. In such a SAF, multiple magnetic layers interleaved with thin layer(s) of Ru or other material may be used. The pinned layer 110 may also be another multilayer. Although a magnetization is not depicted in FIG. 2, the pinned layer 110 may have a perpendicular anisotropy energy that exceeds the out-of-plane demagnetization energy. Thus, the pinned layer 110 may have its magnetic moment oriented perpendicular to plane. In other embodiments, the magnetic moment of the pinned layer 110 is in-plane. Other orientations of the magnetization of the pinned layer 110 are possible.

The spacer layer 120 is nonmagnetic. In some embodiments, the spacer layer 120 is an insulator, for example a tunneling barrier. In such embodiments, the spacer layer 120 may include crystalline MgO, which may enhance the TMR of the magnetic junction as well as the perpendicular magnetic anisotropy of the free layer 130. A crystalline MgO nonmagnetic spacer layer 120 may also aid in providing a BCC crystal structure for Co in the free layer 130. In other embodiments, the spacer layer 120 may be a conductor, such as Cu. In alternate embodiments, the spacer layer 120 might have another structure, for example a granular layer including conductive channels in an insulating matrix.

The free layer 130 is magnetic and thermally stable at operating temperatures. In some embodiments, therefore, the thermal stability coefficient, Δ, of the free layer 130 is at least sixty at operating temperatures (e.g. at or somewhat above room temperature). In some embodiments, the free layer 130 is a multilayer. For example, the free layer 130 maybe a SAF and/or may include multiple adjoining ferromagnetic layers that are exchange coupled.

The free layer 130 also includes body-centered cubic (BCC) Co. In some embodiments, the BCC Co is in the form of layer(s) within the free layer 130. Although termed BCC, the actual structure may be considered to be tetragonal as all axes of the unit cell may not have the same length. Stated differently, as used herein, BCC Co includes body-centered cubic Co, body-centered tetragonal Co and analogous crystal structures. It is also noted that for bulk Co, the crystal structure is hexagonal close packed (HCP). Thus, BCC Co may be considered to exclude an HCP crystal structure. In order to assure that at least part of the free layer 130 includes BCC Co, the free layer 130 may include one or more layers of BCC Co.

Various mechanisms may be used to provide the BCC Co in the free layer. For example, a lower thickness, particularly in conjunction with epitaxial growth, might be used. For example, the free layer 130 may include BCC CO layer(s) having a thickness of not more than twenty Angstroms. In some embodiments, the BCC Co layer(s) in the free layer 130 have a thickness of not more than twelve Angstroms. In some such embodiments, the BCC Co layers have a thickness of at least six Angstroms. In some embodiments, the layers are at least six Angstroms and not more than ten Angstroms thick. In some such embodiments, the BCC Co layers may be at least eight Angstroms and not more than ten Angstroms thick. In some embodiments, the thickness of the BCC Co may be measured by the number of monolayers used. For example, in some embodiments, at least two and not more than to sixteen monolayers of BCC Co may be present in the free layer 130. In other embodiments, four through twelve monolayers of BCC Co may be used. In other embodiments, at least four and not more than eight monolayers of BCC Co may be used. However, other thicknesses may be possible. For example, it may be possible to achieve BCC Co layers in the range of forty to eighty Angstroms using molecular beam epitaxy as a deposition technique.

Further, the free layer 130 may include material(s) that promote the growth of BCC Co. For example, layers of materials such as one or more of Cr, Fe, Mo, Tc, W, Re, and/or Os may be included. Such materials have a surface energy greater than that of Co and a BCC crystal structure. This may promote growth of the BCC crystal structure for Co. In some such free layers 130, the materials used to promote the growth of BCC Co may be one or more of Fe, Cr and W.

Growth of BCC Co may also be more generally understood as follows. Note, however, that the exemplary embodiments do not depend upon a particular physical explanation for the growth of BCC Co. The presence of BCC Co may be understood in terms of energies in the system. BCC Co is generally expected to have a greater total energy than face-centered cubic (FCC). In turn, an FCC Co lattice has a greater energy than that of an HCP Co lattice. Consequently, without more, bulk Co tends to have an HCP crystal structure. In the case of epitaxial growth, such as that off a GaAs substrate, the BCC phase has a small (e.g. approximately 0.2%) lattice mismatch compared to the FCC phase. When the thickness of the Co layer is relatively low, interfacial energy attributable to the epitaxial relationship with the substrate may be sufficient to overcome the bulk energy for the transition to the FCC or HCP phase. Consequently, the BCC crystal structure for the Co may be stabilized for lower thicknesses, such as those discussed above. Similarly, the strain energy in the lattice of BCC Co may also factor into the above energy calculation. In general, if the Co may be configured such that the BCC phase is energetically favored, then the Co may have a BCC crystal structure.

In addition to or in lieu of using lower thicknesses of Co to maintain the BCC phase, other mechanisms may be used to configure the energy of the system to favor BCC growth. In some embodiments, the interfacial energy for the Co may be tuned. One mechanism for doing so is to select specific substrate(s), seed layer(s) and/or cap layers. Similarly, layers may be interleaved with BCC Co layers. The interfacial energy at the interfaces between the BCC Co and the remaining layers may result in the BCC phase being the most stable. Defects and impurities/dopants also contribute an additional energy term which could help reduce the total energy of the BCC phase and more readily allow for its existence. As discussed above, strain may also be used to obtain a configuration that makes BCC Co energetically favorable. In many embodiments, the interfacial energy and reduced thickness, discussed above, may be used in conjunction with other mechanisms to make BCC Co more energetically favorable.

Defects may also be used to configure the energy of the Co layer to favor a BCC crystal structure. Methods for creating such defects include but are not limited to variation of deposition and process parameters. For example, the deposition rate, deposition temperature, deposition pressure, post-deposition annealing, and other processing conditions may be modified. Limiting surface diffusivity of atoms while increasing the incoming flux of atoms generally causes film growth without adequate relaxation leading to higher defect density.

Dopants may also be used to make the BCC structure more favorable. In some embodiments, dopants may be introduced to create defects. These defects that make the BCC phase more stable. Dopants may also be introduced to enhance the BCC phase. For example structural dopants may enhance BCC tendencies, which are known to create the BCT/FCT structure in bulk compounds. Such structural dopants may include dopants that are BCC in their pure bulk form such as Cr, Fe, Mo, Nb, Ta, V, and W as well as dopants that are FCC in the pure bulk form, such as Al, Ir, Ni, Pd, Pt, and Rh. Regardless of which general purpose dopants are introduced for, they affect the behavior of the film during growth, upon annealing, and under subsequent processing. Certain dopants may also be used to manipulate the energy barriers to atomic motion. Particularly during growth, this effect may be used to selectively increase or decrease diffusion rate along specific crystalline planes. For example, the energy barriers may be reduced preferentially for 111 and 110 planes to aid growth on the 100 plane. This is similar to surfactant assisted growth. It should also be noted that the theoretical moment of BCC Co is relatively high, around 1.6-1.7 bohr magnetons. This magnitude is not far from FCC and HCP cobalt. Another effect of the impurities/defects would be to lower the moment, allowing Ms to be tuned to a desired level to facilitate STT switching.

Other materials may also be incorporated into the free layer 130 to provide the desired magnetic characteristics, such as the desired magnetoresistance and switching current. For example, the free layer 130 may include one or more layers of Fe, CoFe and/or CoFeB. Note that in some embodiments, CoFeB generally includes not more than ten atomic percent of B. In some embodiments, the free layer 130 may include seed or capping layers, such as MgO, which enhance the perpendicular magnetic anisotropy of the free layer 130. In some embodiment, MgO assists in imposing the BCC structure on the Co in the free layer 130. Thus, use of the BCC Co in the free layer 130 may be part of the engineering of the free layer 130 to have the desired characteristics.

The magnetic junction 100 and free layer 130 may have improved performance. The free layer 130 may be switched using spin transfer torque. Thus, a more localized physical phenomenon may be used to write to the free layer 130. The magnetic properties of the free layer 130 and magnetic junction 100 may also be configured. For example, an enhanced magnetoresistance/tunneling magnetoresistance, lower switching current, and/or perpendicular anisotropy may be achieved. Thus, the magnetic junction 100 may have improved performance.

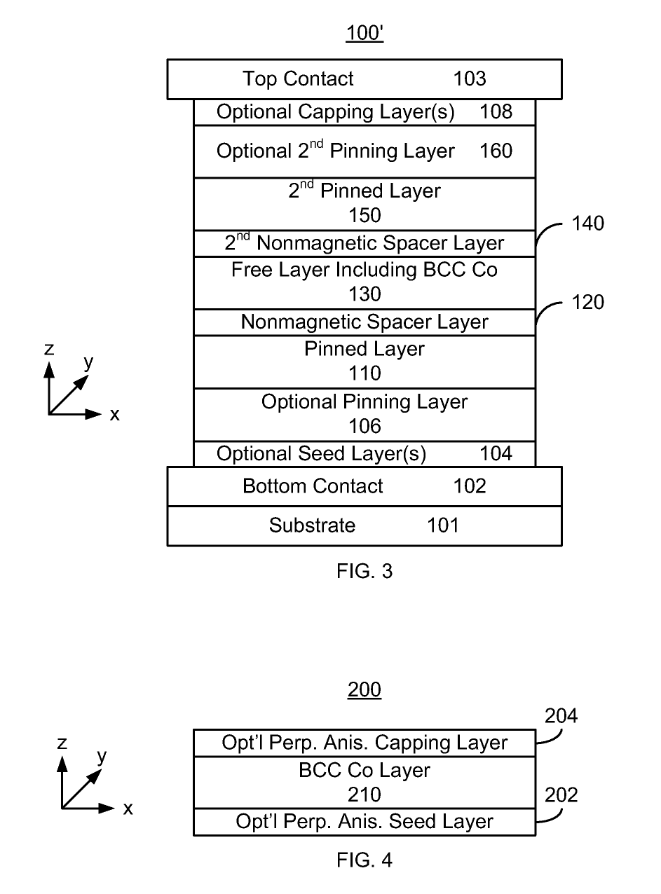

FIG. 3 depicts another exemplary embodiment of a magnetic junction 100′ usable in a magnetic device. The magnetic device in which the magnetic substructure 100′ is used may be used in a variety of applications. For example, the magnetic device, and thus the magnetic substructure, may be used in a magnetic memory such as an STT-MRAM. For clarity, FIG. 3 is not to scale. The magnetic junction 100′ is analogous to the magnetic junction 100. Consequently, analogous components are labeled similarly. The magnetic junction 100′ thus includes a pinned layer 110, a nonmagnetic spacer layer 120, and a free layer 130 analogous to those depicted in FIG. 2. Also shown are an underlying substrate 101, bottom contact 102, optional seed layer(s) 104, optional capping layer(s) 108 and top contact 103 that are analogous to those shown in FIG. 2. Although layers 110, 120, and 130 are shown with a particular orientation with respect to the substrate 101, this orientation may vary in other embodiments. For example, the pinned layer 110 may be closer to the top (furthest from a substrate) of the magnetic junction 100. The magnetic junction 100 is also configured to allow the free layer 130 to be switched between stable magnetic states when a write current is passed through the magnetic junction 100. Thus, the free layer 130 is switchable utilizing spin transfer torque.

The magnetic junction 100′ also includes an additional nonmagnetic spacer layer 140 and an additional pinned layer 150 analogous to the nonmagnetic spacer layer 120 and the pinned layer 110. Also shown is optional pinning layer 160, which may be omitted.

The pinned layer 150 is magnetic and may have its magnetization pinned, or fixed, in a particular direction during at least a portion of the operation of the magnetic junction. Although depicted as a simple layer, the pinned layer 150 may include multiple layers. For example, the pinned layer 150 may be a SAF. Although a magnetization is not depicted in FIG. 3, the pinned layer 150 may have a perpendicular anisotropy energy that exceeds the out-of-plane demagnetization energy. Thus, the pinned layer 150 may have its magnetic moment oriented perpendicular to plane. In other embodiments, the magnetic moment of the pinned layer 150 is in-plane. Other orientations of the magnetization of the pinned layer 150 are possible. In some embodiments, the magnetizations of the pinned layers 110 and 150 are oriented antiparallel (dual state), which may result improved writing via spin transfer torque. In other embodiments, the magnetizations of the pinned layers 110 and 150 are oriented parallel, which may enhance magnetoresistance. In other embodiments, the orientations of the magnetic moments of the pinned layers 110 and 150 may be set differently for read and write operations. In still other embodiments, other orientations are possible.

The spacer layer 140 is nonmagnetic. In some embodiments, the spacer layer 140 is an insulator, for example a tunneling barrier. In such embodiments, the spacer layer 140 may include crystalline MgO, which may enhance the TMR of the magnetic junction as well as the perpendicular magnetic anisotropy of the free layer 130. In such embodiment, the use of MgO may also assist in establishing a BCC crystal structure for Co in the free layer 130. In other embodiments, the spacer layer 140 may be a conductor, such as Cu. In alternate embodiments, the spacer layer 140 might have another structure, for example a granular layer including conductive channels in an insulating matrix.

As discussed above, the free layer 130 includes BCC Co. Thus, the free layer 130 may include multiple BCC Co layers or a single BCC Co layer. The free layer 130 may include one or more layers of such BCC Co. In some embodiments, these layers have a thickness of at least six Angstroms and not more than twelve Angstroms. In some such embodiments, the BCC Co layers have a thickness of at least six Angstroms. In some embodiments, the layers are at least six Angstroms and not more than ten Angstroms thick. In some such embodiments, the Co layers may be at least eight Angstroms and not more than ten Angstroms thick. The BCC Co thickness may also be considered in the context of monolayers. For example, four through sixteen monolayers of BCC Co may be used. In some embodiments, up to twelve monolayers of BCC Co may be present in the free layer 130. In other embodiments, at least four and not more than eight monolayers may be used.

Further, the free layer 130 may include material(s) that promote the growth of BCC Co. for example, materials such as one or more of Cr, Fe, Mo, Tc, W, Re, and/or Os may be included. In some such free layers 130, the materials used to promote the growth of BCC Co may be one or more of Fe, Cr and W. Other materials may also be incorporated into the free layer 130 to provide the desired magnetic characteristics, such as the desired magnetoresistance and switching current. For example, the free layer 130 may include one or more layers of Fe, CoFe and/or CoFeB. Note that in some embodiments, CoFeB generally includes not more than ten atomic percent of B. In some embodiments, the free layer 130 may include seed or capping layers, such as MgO, which enhance the perpendicular magnetic anisotropy of the free layer 130. The MgO may also be used to assist in providing Co that has a BCC crystal structure. Thus, use of the BCC Co in the free layer 130 may be part of the engineering of the free layer 130 to have the desired characteristics.

The magnetic junction 100′ and free layer 130 may have improved performance. The free layer 130 may be switched using spin transfer torque. Thus, a more localized physical phenomenon may be used to write to the free layer 130. The magnetic properties of the free layer 130 and magnetic junction 100′ may also be configured. For example, an enhanced magnetoresistance/tunneling magnetoresistance, lower switching current, and/or perpendicular anisotropy may be achieved. Thus, the magnetic junction 100′ may have improved performance.

FIG. 4 depicts an exemplary embodiment of a magnetic structure 200 including BCC Co that may be used in the free layer of the magnetic junction, for example in the free layer 130 in the magnetic junction 100 and/or 100′. For clarity, FIG. 4 is not to scale. The BCC Co magnetic structure 200 may be used as the free layer or may form a portion of the free layer.

The BCC Co magnetic structure 200 may include optional perpendicular anisotropy seed layer 202 and/or optional perpendicular anisotropy capping layer 204. For example, crystalline MgO may be used as the layer 202 and/or 204. However, in other embodiments, the layers 202 and/or 204 may be omitted. For example, if the BCC Co magnetic structure 200 is used in the magnetic junction 100 and/or 100′ and crystalline MgO is used for the nonmagnetic spacer layer(s) 120 and/or 140, the layers 202 and/or 204 might be omitted. In some embodiments, crystalline MgO may be used for the layers 202 and/or 204. Use of crystalline MgO for the seed layer 202 and/or the capping layer 204 may aid in assuring that the BCC Co layer 210 has a BCC crystal structure.

The BCC Co layer 210 is desired to remain BCC and not transition to the bulk HCP crystal structure. Thus, the BCC Co layer 210 may have a thickness of at least six Angstroms and not more than twelve Angstroms. In some such embodiments, the BCC Co layer 210 has a thickness of at least six Angstroms. In some embodiments, the BCC Co layer 210 is at least six Angstroms and not more than ten Angstroms thick. In some such embodiments, the BCC Co layer 210 may be at least eight Angstroms and not more than ten Angstroms thick. The thickness of the layer 210 may also be considered in the context of monolayers. For example, four through sixteen monolayers of BCC Co may be present in the BCC Co layer 210. In some embodiments, up to twelve monolayers of BCC Co may be used in the BCC Co layer 140. In other embodiments, at least four and not more than eight monolayers may be used.

Using the BCC Co magnetic structure 200, the free layer 130 of the magnetic junction 100 and/or 100′ may be provided. Consequently, the benefits described herein may be achieved.

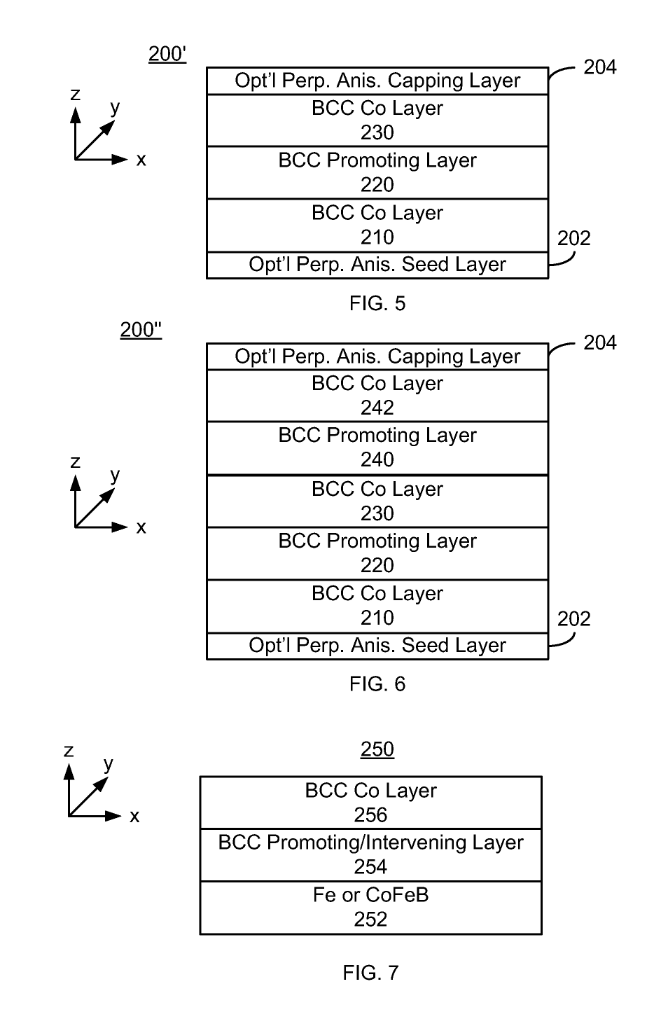

FIG. 5 depicts an exemplary embodiment of a magnetic structure 200′ including BCC Co that may be used in the free layer of the magnetic junction, for example in the free layer 130 in the magnetic junction 100 and/or 100′. For clarity, FIG. 5 is not to scale. The BCC Co magnetic structure 200′ may be used as the free layer or may form a portion of the free layer. The BCC Co magnetic structure 200′ is analogous to the magnetic structure 200. Consequently, similar components have analogous labels. For example, the BCC Co magnetic structure 200′ includes optional perpendicular anisotropy seed and capping layers 202 and 204 that are analogous to the layers 202 and 204 in the magnetic structure 200. However, in other embodiments, the layers 202 and/or 204 may be omitted.

The BCC Co layer 210 is analogous to the BCC Co layer 210 depicted in FIG. 4. The BCC Co layer 230 is analogous to the BCC Co layer 210. Thus, the BCC Co layer 230 is desired to remain BCC and not transition to the bulk HCP crystal structure. The thickness of the BCC Co layer 230 may thus have the same range(s) as the BCC Co layer 210. The seed layer(s) 202 and 204 may be used to promote a BCC crystal structure in addition to or in lieu of the BCC promoting layer 220.

The BCC Co structure 200′ also includes BCC promoting layer 220. The BCC promoting layer 220 may increase the interval of thicknesses over which the layers 210 and 230 continue to have a BCC crystal structure. For example, the BCC promoting layer 220 may include Cr, Fe and/or W. In some embodiments, the BCC promoting layer 220 may include a material that has a surface energy that is greater than the surface energy of Co and has a BCC crystal structure. Such materials may include Cr, Mo, Tc, W, R, and Os. Of these, Cr and W may be preferred. In some embodiments, the BCC promoting layer 220 may be desired to have lattice parameter(s) that are within ten percent of that of BCC Co. However, in other embodiments, other lattice parameters may be used. In some embodiments, the BCC promoting layer 220 has a thickness of at least five Angstroms and not more than one hundred Angstroms. In some such embodiments, the thickness of the BCC promoting layer 220 is at least five and not more than twenty Angstroms. Because of the use of the BCC promoting layer 220, the BCC Co layer(s) 210 and/or 230 may remain with a BCC crystal structure over a wider thickness range. For example, in some embodiments, the BCC Co layer(s) 210 and/or 230 may remain with a BCC crystal structure for thicknesses up to twenty Angstroms or more.

Using the BCC Co magnetic structure 200′, the free layer 130 of the magnetic junction 100 and/or 100′ may be provided. Consequently, the benefits described herein may be achieved.

FIG. 6 depicts another exemplary embodiment of a magnetic structure 200″ including BCC Co that may be used in the free layer of the magnetic junction, for example in the free layer 130 in the magnetic junction 100 and/or 100′. For clarity, FIG. 6 is not to scale. The BCC Co magnetic structure 200″ may be used as the free layer or may form a portion of the free layer. The BCC Co magnetic structure 200″ is analogous to the magnetic structure 200 and/or 200′. Consequently, similar components have analogous labels. For example, the BCC Co magnetic structure 200″ includes optional perpendicular anisotropy seed and capping layers 202 and 204 that are analogous to the layers 202 and 204 in the magnetic structure(s) 200 and/or 200′. However, in other embodiments, the layers 202 and/or 204 may be omitted.

The BCC Co layer 210, BCC promoting layer 220 and BCC Co layer 230 are analogous to the layers 210, 220 and 230 depicted in FIGS. 3-4. Thus, the structure and function of the layers 210, 220 and 230 are analogous to those described above. In addition, the BCC Co structure includes BCC promoting layer 240 and BCC Co layer 242. The BCC promoting layer 240 is analogous to the BCC promoting layer 220. The BCC promoting layer 220 may increase the interval of thicknesses over which the layers 210, 230 and 242 continue to have a BCC crystal structure. The BCC promoting layer 240 may also include analogous materials to those described for the BCC promoting layer 220. The BCC Co layer 242 is analogous to the BCC Co layer(s) 210 and/or 230. Because of the presence of the layers 220 and 240, the layers 210, 230 and 242 may remain with a BCC crystal structure to higher thicknesses. The seed layer(s) 202 and 204 may be used to promote a BCC crystal structure in addition to or in lieu of the BCC promoting layers 220 and/or 240. Thus, the BCC Co and BCC promoting layers may be interleaved in order to provide a thicker magnetic structure 200″.

Using the BCC Co magnetic structure 200″, the free layer 130 of the magnetic junction 100 and/or 100′ may be provided. Consequently, the benefits described herein may be achieved.

FIG. 7 depicts an exemplary embodiment of a magnetic structure 250 including BCC Co that may be used in the free layer of the magnetic junction, for example in the free layer 130 in the magnetic junction 100 and/or 100′. For clarity, FIG. 7 is not to scale. The BCC Co magnetic structure 250 may be used as the free layer or may form a portion of the free layer.

The BCC Co magnetic structure 250 may include optional perpendicular anisotropy seed layer and/or optional perpendicular anisotropy capping layer that are analogous to the layers 202 and/or 204 depicted in FIGS. 4-6. For example, crystalline MgO may be used as the layer. However, in other embodiments, the seed and/or capping layers may be omitted. For example, if the BCC Co magnetic structure 250 is used in the magnetic junction 100 and/or 100′ and crystalline MgO is used for the nonmagnetic spacer layer(s) 120 and/or 140, the seed and/or capping layers might be omitted. In some embodiments, crystalline MgO may be used for the seed and/or capping layers. Use of crystalline MgO for the seed layer and/or the capping layer may aid in assuring that the BCC Co layer has a BCC crystal structure.

The BCC Co magnetic structure 250 includes an Fe or CoFeB layer 252, BCC promoting/boron attracting layer 254 and BCC Co layer 256. The BCC promoting layer 254 is analogous to the layer 220. The B dopant in CoFeB may be greater than or equal to zero atomic percent and not more than thirty atomic percent. In some such embodiments, the B dopant concentration is not more than twenty atomic percent. The Fe/CoFeB layer 252 may be used to provide the desired magnetic properties, such as softness and magnetoresistance. In some embodiments, the Fe/CoFeB layer 252 may be at least five Angstroms and not more than thirty Angstroms thick. In some such embodiments, the thickness of the Fe/CoFeB layer 252 is at least eight Angstroms and not more than twenty Angstroms.

The BCC Co magnetic structure 250 also includes an intervening layer 254. The intervening layer 254 may be used to promote the BCC crystal structure of the layer 256 in a manner analogous to the layers 220 and 240, described above. In addition to promoting crystallization of the BCC Co layer 256, the intervening layer 254 may also attract boron. For example, the intervening layer 254 may include one or more of Ta, W, Zr, Hf and Bi. In some embodiments, the layer 254 consists of one or more of Ta, W, Zr, Hf and Bi. Consequently, the layer 254 may reduce or prevent the diffusion of B from a CoFeB layer 252 into the BCC Co layer 256. The BCC Co layer 256 is desired to remain BCC and not transition to the bulk HCP crystal structure. Thus, the BCC Co layer 256 may have a thickness in the ranges described above.

Using the BCC Co magnetic structure 250, the free layer 130 of the magnetic junction 100 and/or 100′ may be provided. Consequently, the benefits described herein may be achieved.

FIG. 8 depicts an exemplary embodiment of a magnetic structure 260 including BCC Co that may be used in the free layer of the magnetic junction, for example in the free layer 130 in the magnetic junction 100 and/or 100′. For clarity, FIG. 8 is not to scale. The BCC Co magnetic structure 260 may be used as the free layer or may form a portion of the free layer.

The BCC Co magnetic structure 260 includes the BCC magnetic structure 250. In addition, the BCC Co magnetic structure 260 includes optional seed layer 262 and capping layer 264. These layers 262 and 264 are analogous to the layers 202 and 204, respectively, depicted in FIGS. 4-6. For example, crystalline MgO may be used as the layer. The Fe/CoFeB layer 252, BCC promoting/intervening layer 254 and BCC Co Layer 256 are analogous to the layers 252, 254 and 256 depicted in FIG. 7.

Using the BCC Co magnetic structure 260, the free layer 130 of the magnetic junction 100 and/or 100′ may be provided. Consequently, the benefits described herein may be achieved.

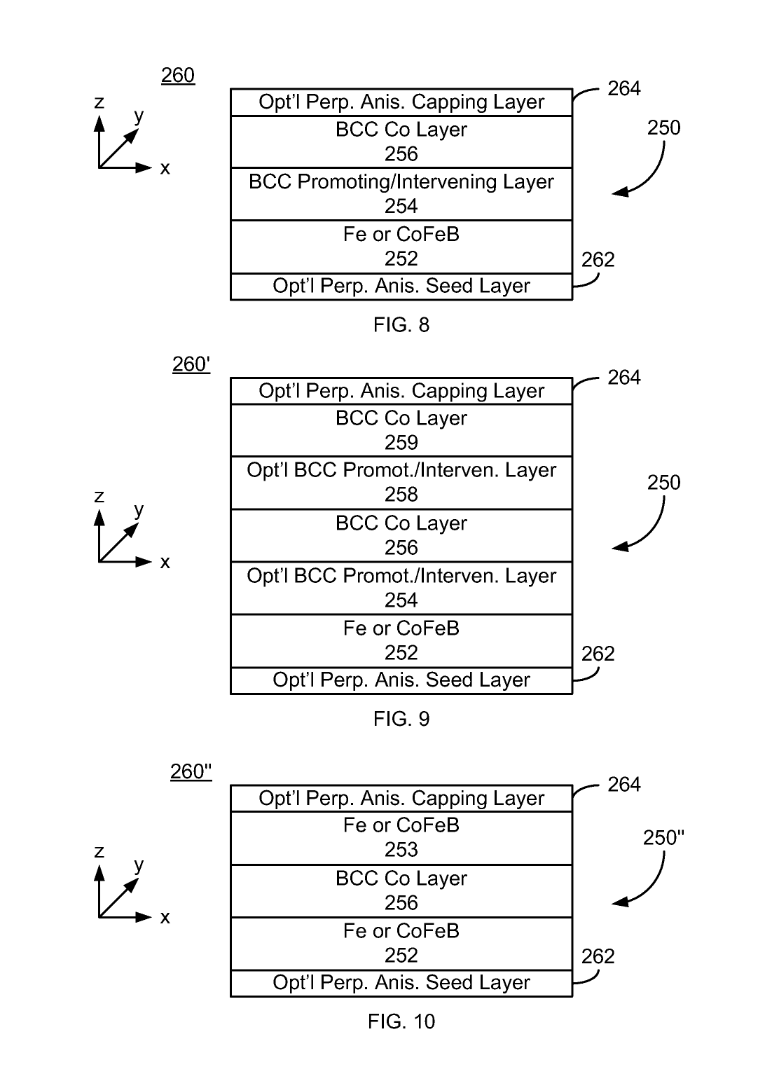

FIG. 9 depicts an exemplary embodiment of a magnetic structure 260′ including BCC Co that may be used in the free layer of the magnetic junction, for example in the free layer 130 in the magnetic junction 100 and/or 100′. For clarity, FIG. 9 is not to scale. The BCC Co magnetic structure 260′ may be used as the free layer or may form a portion of the free layer. The BCC Co magnetic structure 260′ is analogous to the magnetic structure 260. Consequently, similar components have analogous labels. For example, the BCC Co magnetic structure 260′ includes optional perpendicular anisotropy seed and capping layers 262 and 264 that are analogous to the layers 262 and 264 in the magnetic structure 200. However, in other embodiments, the layers 262 and/or 264 may be omitted.

The Fe or CoFeB layer 252, optional BCC promoting/intervening layer 254 and BCC Co layer 256 are analogous to those depicted in FIGS. 7 and 8. In addition the BCC Co magnetic structure 260′ may include an additional BCC promoting/intervening layer 258 and BCC Co layer 259. The BCC promoting layer 258 may be analogous to the layer 254 and/or to the layer(s) 220 and 240 depicted in FIGS. 4-6. Thus, the structure, function, and materials used for the layers 258 and 259 may be analogous to those used for the layers 254/220/240 and 210, 230, 240 and/or 256.

Using the BCC Co magnetic structure 260′, the free layer 130 of the magnetic junction 100 and/or 100′ may be provided. Consequently, the benefits described herein may be achieved.

FIG. 10 depicts an exemplary embodiment of a magnetic structure 260″ including BCC Co that may be used in the free layer of the magnetic junction, for example in the free layer 130 in the magnetic junction 100 and/or 100′. For clarity, FIG. 10 is not to scale. The BCC Co magnetic structure 260″ may be used as the free layer or may form a portion of the free layer. The BCC Co magnetic structure 260″ is analogous to the magnetic structure(s) 260 and/or 260′. Consequently, similar components have analogous labels. For example, the BCC Co magnetic structure 260″ includes optional perpendicular anisotropy seed and capping layers 262 and 264 that are analogous to the layers 262 and 264 in the magnetic structure 200. However, in other embodiments, the layers 262 and/or 264 may be omitted.

The Fe or CoFeB layer 252 and BCC Co layer 256 are analogous to those depicted in FIGS. 7-9. In addition the BCC Co magnetic structure 260″ may include an additional Fe or CoFe layer 253. The Fe or CoFe layer 253 may be analogous to the layer 252. Thus, the structure, function, and materials used for the layers 252, 253 and 256 may be analogous to those used for the layers 252 and 256.

Using the BCC Co magnetic structure 260″, the free layer 130 of the magnetic junction 100 and/or 100′ may be provided. Consequently, the benefits described herein may be achieved.

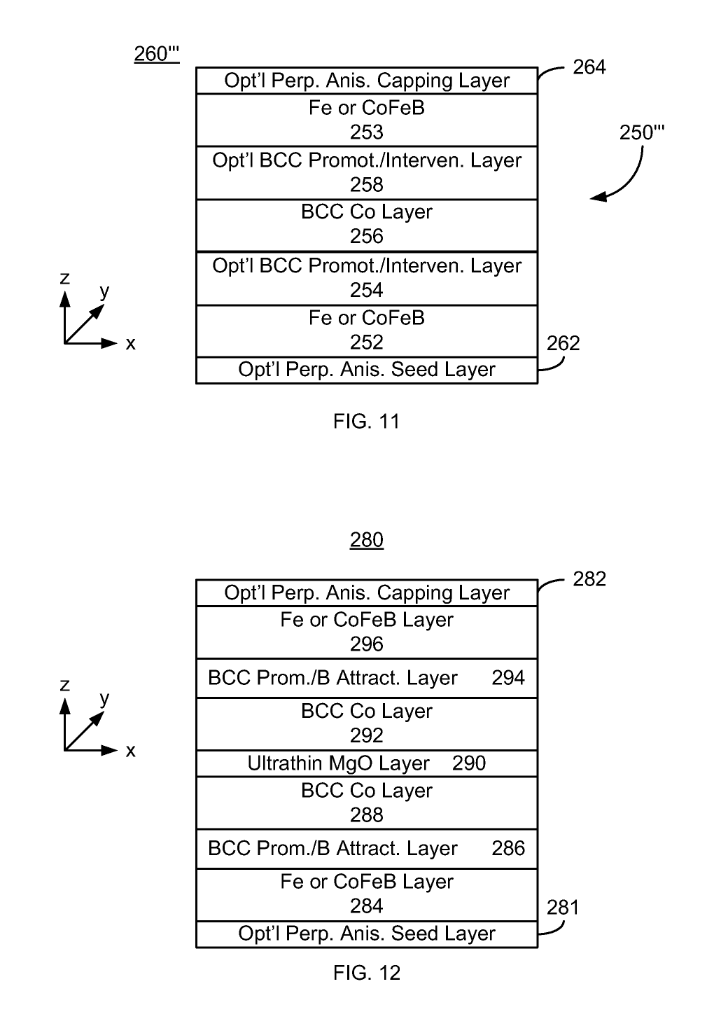

FIG. 11 depicts an exemplary embodiment of a magnetic structure 260′″ including BCC Co that may be used in the free layer of the magnetic junction, for example in the free layer 130 in the magnetic junction 100 and/or 100′. For clarity, FIG. 11 is not to scale. The BCC Co magnetic structure 260′″ may be used as the free layer or may form a portion of the free layer. The BCC Co magnetic structure 260′″ is analogous to the magnetic structure(s) 260, 260′ and/or 260″. Consequently, similar components have analogous labels. For example, the BCC Co magnetic structure 260′″ includes optional perpendicular anisotropy seed and capping layers 262 and 264 that are analogous to the layers 262 and 264 in the magnetic structure 200. However, in other embodiments, the layers 262 and/or 264 may be omitted.

The Fe or CoFeB layers 252 and 253, BCC Co layer 256 and BCC promoting/intervening layers 254 and 258 are analogous to those depicted in FIGS. 7-10. Thus, the structure, function, and materials used for the layers 252, 253, 254, 256 and 258 may be analogous to those used for described above.

FIG. 12 depicts an exemplary embodiment of a magnetic structure 280 including BCC Co that may be used in the free layer of the magnetic junction, for example in the free layer 130 in the magnetic junction 100 and/or 100′. For clarity, FIG. 12 is not to scale. The BCC Co magnetic structure 280 may be used as the free layer or may form a portion of the free layer.

The BCC Co magnetic structure 280 may include optional perpendicular anisotropy seed layer 281 and/or optional perpendicular anisotropy capping layer 282 that are analogous to the layers 202 and/or 204 depicted in FIGS. 4-6. For example, crystalline MgO may be used as the layer. However, in other embodiments, the seed and/or capping layers may be omitted. For example, if the BCC Co magnetic structure 280 is used in the magnetic junction 100 and/or 100′ and crystalline MgO is used for the nonmagnetic spacer layer(s) 120 and/or 140, the seed and/or capping layers might be omitted. Use of crystalline MgO for the seed layer and/or the capping layer may aid in assuring that the BCC Co layer has a BCC crystal structure.

The BCC Co magnetic structure 280 includes an Fe or CoFeB layer 284, a BCC promoting/boron attracting layer 286, a first BCC Co layer 288, an ultrathin MgO layer 290, a second BCC Co layer 292, a second BCC promoting/B attracting layer 294 and a second Fe or CoFeB layer 296. The Fe or CoFeB layers 284 and 296 are analogous to the layers 252 and 253. The BCC promoting/B attracting layers 286 and 294 are analogous to the layers 254 and 258. The BCC Co layers 288 and 292 are analogous to the layers 210, 230, 242 and/or 256. The BCC Co magnetic structure 280 may thus be viewed as including two structures analogous to the magnetic structure 250.

In addition, the BCC Co magnetic structure 280 includes an ultrathin MgO layer 290. The ultrathin MgO layer 290 may have a thickness of one to two monolayers or less. For example, in some embodiments, the ultrathin MgO layer may be not more than two Angstroms thick. Thus, the ultrathin MgO layer may not form a continuous layer. The ultrathin MgO layer is desired to be thin in order to ensure that the resistance of the magnetic junction does not become too high. The ultrathin MgO layer 290 may aid in imposing crystal order on the BCC Co layers 288 and 292 and may enhance magnetoresistance. The thickness of the ultrathin MgO layer 290 is such that the resistance-area product of the junction remains in the desired range of at least one and not more than one hundred Ω-μm². In some such embodiments, the resistance-area product of the junction is at least two and not more than fifty Ω-μm².

The BCC Co magnetic structure 280 may include optional perpendicular anisotropy seed layer 281 and/or optional perpendicular anisotropy capping layer 282 that are analogous to the layers 202 and/or 204 depicted in FIGS. 4-6. For example, crystalline MgO may be used as the layer. However, in other embodiments, the seed and/or capping layers may be omitted. For example, if the BCC Co magnetic structure 280 is used in the magnetic junction 100 and/or 100′ and crystalline MgO is used for the nonmagnetic spacer layer(s) 120 and/or 140, the seed and/or capping layers might be omitted. Use of crystalline MgO for the seed layer and/or the capping layer may aid in assuring that the BCC Co layer has a BCC crystal structure.

Using the BCC Co magnetic structure 280, the free layer 130 of the magnetic junction 100 and/or 100′ may be provided. Consequently, the benefits described herein may be achieved.

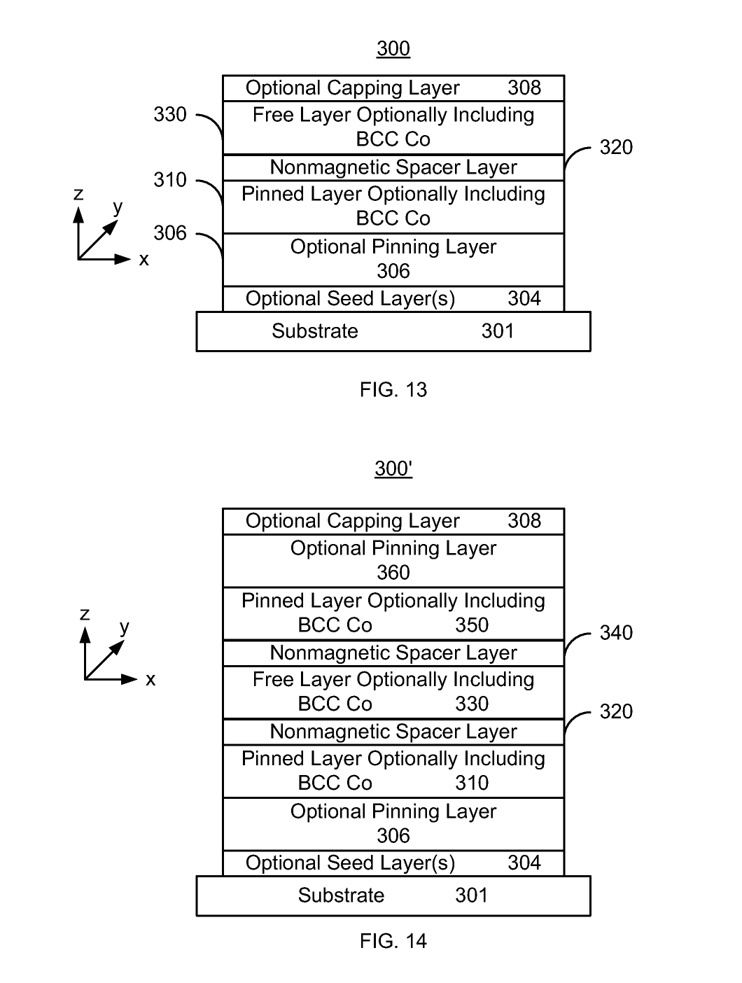

FIG. 13 depicts an exemplary embodiment of a magnetic junction 300 as well as surrounding structures. For clarity, FIG. 13 is not to scale. The magnetic junction may be used in a magnetic device such as a spin transfer torque random access memory (STT-RAM) and, therefore, in a variety of electronic devices. The magnetic junction 300 includes a pinned layer 310, a nonmagnetic spacer layer 320, and a free layer 330. Also shown is an underlying substrate 301 in which devices including but not limited to a transistor may be formed. For simplicity, contacts are not shown. Although layers 310, 320, and 330 are shown with a particular orientation with respect to the substrate 301, this orientation may vary in other embodiments. For example, the pinned layer 310 may be closer to the top (furthest from a substrate) of the magnetic junction 300. Also shown are optional seed layer 304, optional pinning layer 306, and optional capping layer 308. The optional pinning layer 306 may be used to fix the magnetization (not shown) of the pinned layer 310. In some embodiments, the optional pinning layer 306 may be an AFM layer or multilayer that pins the magnetization (not shown) of the pinned layer 310 by an exchange-bias interaction. However, in other embodiments, the optional pinning layer 306 may be omitted or another structure may be used. The magnetic moments of the pinned layer 310 and free layer 330 may be in plane, perpendicular to plane, or arranged in another manner.

The pinned layer 310 and free layer 330 are analogous to the layers 110 and 130, respectively. Thus, the free layer 330 may include BCC Co. In some embodiments, the free layer 330 includes one or more of the BCC Co magnetic structures 200, 200′, 200″, 250, 260, 260′, 260″, 260′″, 280 and/or 280″. In addition, the pinned layer 310 may include BCC Co. In some embodiments, the pinned layer 310 includes one or more of the BCC Co magnetic structures 200, 200′, 200″, 250, 260, 260′, 260″, 260′″, 280 and/or 280″.

The magnetic junction 300 thus includes a pinned layer 310 and/or a free layer having BCC Co therein. As such, benefits analogous to those enjoyed by the magnetic junction 100 might be achieved.

FIG. 14 depicts another exemplary embodiment of a magnetic junction 300′ usable in a magnetic device. The magnetic device in which the magnetic substructure 300′ is used may be used in a variety of applications. For example, the magnetic device, and thus the magnetic substructure, may be used in a magnetic memory such as an STT-MRAM. For clarity, FIG. 14 is not to scale. The magnetic junction 300′ is analogous to the magnetic junction 300. Consequently, analogous components are labeled similarly. The magnetic junction 300′ thus includes a pinned layer 310, a nonmagnetic spacer layer 320, and a free layer 330 analogous to those depicted in FIG. 13. Also shown are an underlying substrate 301, optional seed layer(s) 304, and optional capping layer(s) 308 analogous to those shown in FIG. 14. The magnetic junction 300′ is also configured to allow the free layer 330 to be switched between stable magnetic states when a write current is passed through the magnetic junction 300′. Thus, the free layer 330 is switchable utilizing spin transfer torque.

The magnetic junction 300′ also includes an additional nonmagnetic spacer layer 340 and an additional pinned layer 350 analogous to the nonmagnetic spacer layer 320 and the pinned layer 310. Also shown is optional pinning layer 360, which may be omitted.

The pinned layer 350 is magnetic and may have its magnetization pinned, or fixed, in a particular direction during at least a portion of the operation of the magnetic junction. Although depicted as a simple layer, the pinned layer 350 may include multiple layers. For example, the pinned layer 350 may be a SAF. Although a magnetization is not depicted in FIG. 14, the pinned layer 350 may have a perpendicular anisotropy energy that exceeds the out-of-plane demagnetization energy. Thus, the pinned layer 350 may have its magnetic moment oriented perpendicular to plane. In other embodiments, the magnetic moment of the pinned layer 350 is in-plane. Other orientations of the magnetization of the pinned layer 350 are possible. In some embodiments, the magnetizations of the pinned layers 310 and 350 are oriented antiparallel (dual state), which may result improved writing via spin transfer torque. In other embodiments, the magnetizations of the pinned layers 310 and 350 are oriented parallel, which may enhance magnetoresistance. In other embodiments, the orientations of the magnetic moments of the pinned layers 310 and 350 may be set differently for read and write operations. In still other embodiments, other orientations are possible.

The additional spacer layer 340 is nonmagnetic. In some embodiments, the spacer layer 340 is an insulator, for example a tunneling barrier. In such embodiments, the spacer layer 340 may include crystalline MgO, which may enhance the TMR of the magnetic junction as well as the perpendicular magnetic anisotropy of the free layer 330. In such embodiment, the use of MgO may also assist in establishing a BCC crystal structure for Co in the free layer 330. In other embodiments, the spacer layer 340 may be a conductor, such as Cu. In alternate embodiments, the spacer layer 340 might have another structure, for example a granular layer including conductive channels in an insulating matrix.

At least one of the pinned layer 310, the free layer 330 and the pinned layer 350 includes BCC Co. In some embodiments, the free layer 330 includes one or more of the BCC Co magnetic structures 200, 200′, 200″, 250, 260, 260′, 260″, 260′″, 280 and/or 280″. In addition, the pinned layer 310 may include BCC Co. In some embodiments, the pinned layer 310 includes one or more of the BCC Co magnetic structures 200, 200′, 200″, 250, 260, 260′, 260″, 260′″, 280 and/or 280″. Similarly, in some embodiments, the pinned layer 340 includes one or more of the BCC Co magnetic structures 200, 200′, 200″, 250, 260, 260′, 260″, 260′″, 280 and/or 280″.

The magnetic junction 300′ thus includes pinned layer(s) 310 and 350 as well as a free layer 330, any through all of which may have BCC Co therein. As such, benefits analogous to those enjoyed by the magnetic junction 100′ might be achieved.

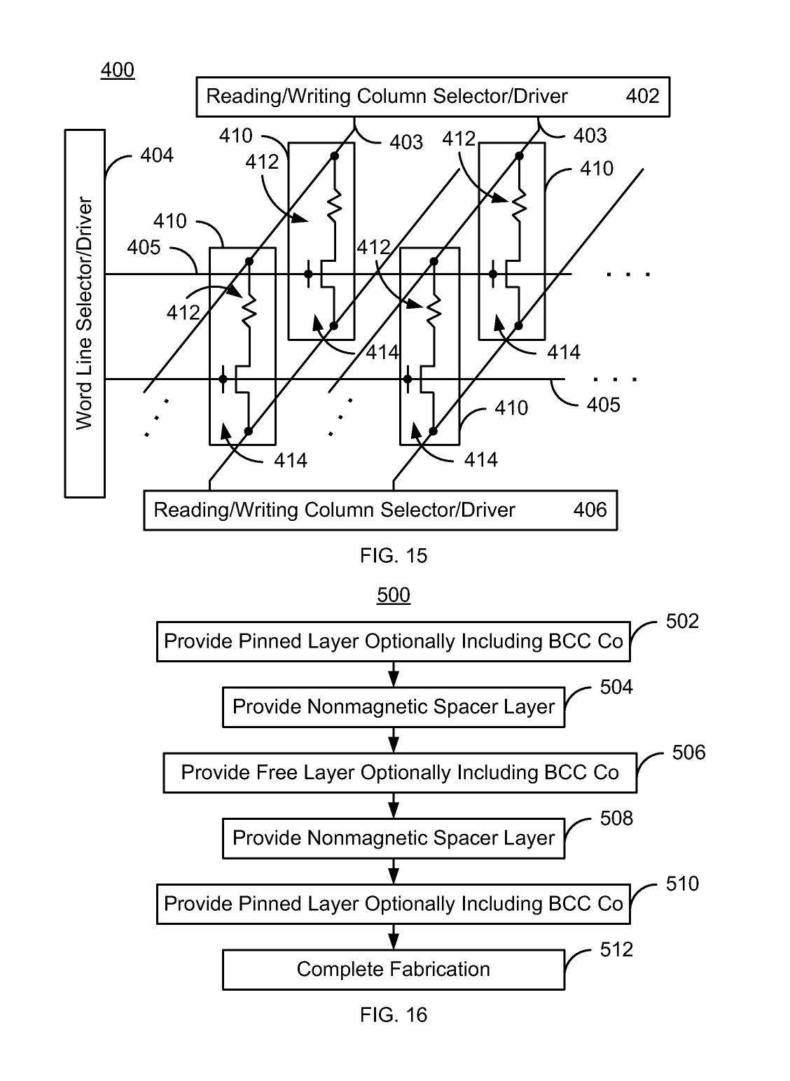

FIG. 15 depicts an exemplary embodiment of a memory 400 that may use one or more of the magnetic junctions 100, 100′, 200 and/or 300′. The magnetic memory 400 includes reading/writing column select drivers 402 and 406 as well as word line select driver 404. Note that other and/or different components may be provided. The storage region of the memory 400 includes magnetic storage cells 410. Each magnetic storage cell includes at least one magnetic junction 412 and at least one selection device 414. In some embodiments, the selection device 414 is a transistor. The magnetic junctions 412 may be one of the magnetic junctions 100, 100′, 300, 300′ disclosed herein utilizing BCC Co. Thus, the free layer and/or pinned layer of the magnetic junctions 412 may include one or more of the BCC Co magnetic structures 200, 200′, 200″, 250, 260, 260′, 260″, 260′″, and/or 280. Although one magnetic junction 412 is shown per cell 410, in other embodiments, another number of magnetic junctions 412 may be provided per cell. As such, the magnetic memory 400 may enjoy the benefits described above.

FIG. 16 depicts an exemplary embodiment of a method 500 for fabricating magnetic substructure. For simplicity, some steps may be omitted or combined. The method 300 is described in the context of the magnetic junctions 100, 100′, 300 and 300′. However, the method 500 may be used on other magnetic junctions. Further, the method 500 may be incorporated into fabrication of magnetic memories. Thus the method 500 may be used in manufacturing a STT-MRAM or other magnetic memory.

The pinned layer 110/110′/310/310′ that may include BCC Co is provided, via step 502. Step 502 may include depositing the desired materials at the desired thickness of the pinned layer 110/110′/310/310′. The nonmagnetic layer 120/320 is provided, via step 504. Step 504 may include depositing the desired nonmagnetic materials. In addition, the desired thickness of material may be deposited in step 504. The free layer 130/130′/330/330′ is provided, via step 506. The nonmagnetic layer 140/340 may optionally be provided, via step 508. The desired pinning layer 150/250 may optionally be provided, via step 510. Fabricating of the magnetic junction 100, 100′, 300 and/or 300′ may then be completed, via step 512. Consequently, the benefits of the magnetic junction(s) 100, 100′, 300 and/or 300′ may be achieved.

A method and system for providing a magnetic junction and a memory fabricated using the magnetic junction has been described. The method and system have been described in accordance with the exemplary embodiments shown, and one of ordinary skill in the art will readily recognize that there could be variations to the embodiments, and any variations would be within the spirit and scope of the method and system. Accordingly, many modifications may be made by one of ordinary skill in the art without departing from the spirit and scope of the appended claims.

We claim:

1. A magnetic junction for use in a magnetic device comprising:
a pinned layer;
a nonmagnetic spacer layer; and
a free layer, at least one of the pinned layer and the free layer including body-centered cubic (BCC) Co, the nonmagnetic spacer layer residing between the pinned layer and the free layer;
wherein the magnetic junction is configured such that the free layer is switchable between a plurality of stable magnetic states when a write current is passed through the magnetic junction.

2. The magnetic junction of claim 1 wherein the free layer consists of a BCC Co layer.

3. The magnetic junction of claim 2 wherein the free layer has a thickness of at least six Angstroms and not more than twelve Angstroms.

4. The magnetic junction of claim 1 wherein the free layer includes the BCC Co.

5. The magnetic junction of claim 4 wherein the free layer includes:
a first layer, a second layer, and a BCC Co promoting layer between the first layer and the second layer, the BCC Co promoting layer including at least one of Cr, Fe, W, the first layer and the second layer including the BCC Co.

6. The magnetic junction of claim 5 wherein first layer and the second layer each consist of the BCC Co, wherein the first layer has a first thickness of at least six Angstroms and not more than twelve Angstroms, and wherein the second layer has a second thickness of at least six Angstroms and not more than twelve Angstroms.

7. The magnetic junction of claim 6 wherein the first thickness is at least six Angstroms and not more than ten Angstroms and wherein the second thickness is at least six Angstroms and not more than ten Angstroms.

8. The magnetic junction of claim 7 wherein the first thickness is at least eight Angstroms and the second thickness is at least eight Angstroms.

9. The magnetic junction of claim 4 wherein the free layer includes:
a first layer, a second layer, and an MgO layer between the first layer and the second layer, the first layer and the second layer including the BCC Co.

10. The magnetic junction of claim 9 wherein the free layer includes:
a first CoFeB layer, a second CoFeB layer, the first CoFeB layer being between the first layer and the pinned layer, the second layer being between the MgO layer and the second CoFeB layer.

11. The magnetic junction of claim 9 wherein first layer includes a first BCC Co layer and the second layer includes a second BCC Co layer, the first BCC Co layer having a first thickness of at least six Angstroms and not more than twelve Angstroms, the second BCC Co layer having a second thickness of at least six Angstroms and not more than twelve Angstroms.

12. The magnetic junction of claim 11 wherein the first thickness is at least six Angstroms and not more than ten Angstroms and wherein the second thickness is at least six Angstroms and not more than ten Angstroms.

13. The magnetic junction of claim 12 wherein the first thickness is at least eight Angstroms and the second thickness is at least eight Angstroms.

14. The magnetic junction of claim 11 wherein the first layer includes a first boron attraction layer between the BCC Co layer and the first CoFeB layer and wherein the

15. The magnetic junction of claim 4 further comprising:
an additional nonmagnetic spacer layer; and
an additional pinned layer, the additional nonmagnetic spacer layer being between the free layer and the additional pinned layer.

16. A magnetic memory comprising:
a plurality of magnetic storage cells, each of the plurality of magnetic storage cells including at least one magnetic junction, the at least one magnetic junction includes a pinned layer, a nonmagnetic spacer layer and a free layer, at least one of the pinned layer and the free layer including body-centered (BCC) Co, the nonmagnetic spacer layer being between the free layer and the pinned layer, the magnetic junction being configured such that the free layer is switchable between a plurality of stable magnetic states when a write current is passed through the magnetic junction; and
a plurality of bit lines coupled with the plurality of magnetic storage cells.

17. The magnetic memory of claim 15 wherein the free layer consists of a BCC Co layer.

18. The magnetic memory of claim 15 wherein the free layer includes:
a first layer, a second layer, and a BCC Co promoting layer between the first layer and the second layer, the BCC Co promoting layer including at least one of Cr, Fe, W, the first layer and the second layer including the BCC Co.

19. The magnetic memory of claim 15 wherein the free layer includes:
a first layer, a second layer, and an MgO layer between the first layer and the second layer, the first layer and the second layer including the BCC Co.

20. The magnetic memory of claim 19 wherein the free layer includes:
a first CoFeB layer, a second CoFeB layer, the first CoFeB layer being between the first layer and the pinned layer, the second layer being between the MgO layer and the second CoFeB layer.
